(19) United States
(12) Patent Application Publication
(10) Pub. No.: US 2008/0160748 A1
(43) Pub. Date: Jul. 3, 2008

(54) Method of Forming Dielectric Layer of Flash Memory Device

(75) Inventors: Kwon Hong, Seongnam-si (KR); Dong Ho Lee, Seongnam-si (KR); Jae Mun Kim, Seoul (KR); Hee Soo Kim, Seongnam-si (KR); Jae Hyoung Koo, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (KR)

(21) Appl. No.: 11/954,673

(22) Filed: Dec. 12, 2007

(30) Foreign Application Priority Data
Jan. 2, 2007 (KR) 10-2007-00225

(51) Int. Cl. H01L 21/283

(52) U.S. Cl. 438/594; 257/E21.179

(57) ABSTRACT

The present invention relates to a method of forming a dielectric layer of a flash memory device. In a process of forming a dielectric layer of a flash memory device, the dielectric layer may include a first oxide layer, a high dielectric layer, and a second oxide layer is formed. Accordingly, a leakage current characteristic and reliability of the flash memory device can be improved.

### CROSS-REFERENCES TO RELATED APPLICATIONS

Priority is claimed to Korean patent application number 10-2007-00225 filed on Jan. 2, 2007, the disclosure of which is incorporated by reference in its entirety.

### FIELD OF THE INVENTION

The present invention relates to a method of forming a dielectric layer of a flash memory device and, more particularly, to a method of forming a dielectric layer of a flash memory device with improved reliability.

### BACKGROUND OF THE INVENTION

In a flash memory device, a dielectric layer with an oxide/nitride/oxide (ONO) structure is used as an insulating film between a floating gate and a control gate for storing data when the flash memory device is operated. A first oxide layer, a silicon nitride film, and a second oxide layer are sequentially stacked to form a dielectric layer with an ONO structure.

In a Dynamic Random Access Memory (DRAM) device, the electrode area of a capacitor can be increased by applying a three-dimensional structure, such as a cylinder shape or a pin shape, to the capacitor. In the case of a flash memory device, however, it is difficult to apply the above method to the floating gate in view of its structure. Currently, the method of reducing the thickness of the dielectric layer has reached its limit. The method of using the dielectric layer of a high dielectric constant is problematic, as it is difficult to develop new dielectric materials.

### BRIEF SUMMARY OF THE INVENTION

Various embodiments of the present invention are directed towards a method of forming a dielectric layer of a flash memory device that can improve a leakage current characteristics and reliability of the flash memory device. The dielectric layer of various embodiments of the present invention may include a first oxide layer, a high dielectric layer, and a second oxide layer.

In an embodiment of the present invention, a method of forming a dielectric layer of a flash memory device may include forming a tunnel oxide layer and a conductive layer for a floating gate over a semiconductor substrate, patterning the conductive layer for the floating gate and the tunnel oxide layer, forming a dielectric layer that may include a first oxide layer, a high dielectric layer, and a second oxide layer over the overall surface, including the patterned conductive layer for the floating gate, and forming a conductive layer for a control gate over the overall surface, including the dielectric layer.

In an embodiment of the present invention, the conductive layer for the floating gate may include a dual film comprised of an amorphous polysilicon film not containing impurities and a polysilicon film containing impurities. The conductive layer for the floating gate may be deposited to a thickness of approximately 500 to 2000 angstroms using, for example, a Chemical Vapor Deposition (CVD) method. The first oxide layer may be formed to a thickness of approximately 10 to 50 angstroms using, for example, a High Temperature Oxide (HTO) method.

In an embodiment of the present invention, the high dielectric layer may be formed using an Atomic Layer Deposition (ALD) method.

In an embodiment of the present invention, the high dielectric layer may be formed using a nano-mixed method.

In an embodiment of the present invention, the high dielectric layer may be formed by depositing an amorphous film in-situ.

In an embodiment of the present invention, the high dielectric layer may be formed by mixing HfO₂, ZrO₂, La₂O₃, Ta₂O₅, Y₂0₃, and TiO₂ with Al₂O₃. The high dielectric layer may include a ratio of HfO₂, ZrO₂, La₂O₃, Ta₂O₅, Y₂O₃, and TiO₂ to Al₂O₃ in the range of approximately 9:1 to 2:1. The high dielectric layer may be formed to a thickness of approximately 30 to 500 angstroms.

In an embodiment of the present invention, the second oxide layer may be deposited to a thickness of approximately 10 to 50 angstroms using, for example, a HTO method.

In an embodiment of the present invention, the conductive layer for the control gate may be formed using, for example, a polysilicon film having a thickness of approximately 500 to 2000 angstroms. The conductive layer for the control gate may be formed using, for example, a CVD method.

### BRIEF DESCRIPTION OF THE DRAWINGS

FIGS. 1 to 3 are sectional views of a device for illustrating a method of forming an dielectric layer of a flash memory device according to an embodiment of the present invention.

FIG. 4A is a graph illustrating the relationship between the amount of mixture of a gas and a dielectric constant for the method of forming a dielectric layer as shown in FIG. 2.

FIG. 4B illustrates an implantation sequence of a mixed gas for carrying out the method of forming a high dielectric layer as shown in FIG. 2.

### DESCRIPTION OF SPECIFIC EMBODIMENTS

Preferred embodiments of the present invention will be described with reference to the accompanying drawings. These embodiments are used only for illustrative purposes. The invention is not limited thereto.

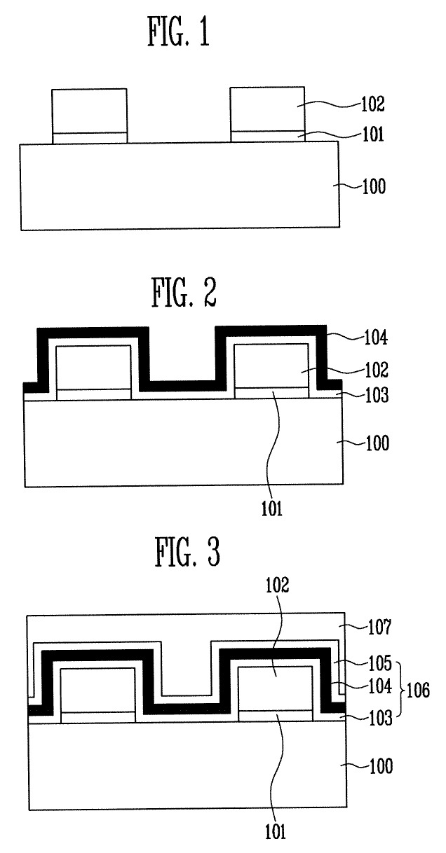

Referring to FIG. 1, a tunnel oxide layer 101, and a conductive layer 102 for a floating gate are formed over a semiconductor substrate 100. The tunnel oxide layer 101 and the conductive layer 102 for the floating gate may be formed sequentially over the semiconductor substrate 100. The conductive layer 102 and the tunnel oxide layer 101 may be etched by an etch process with a hard mask. The conductive layer 102 and the tunnel oxide layer 101 may be etched sequentially.

The conductive layer 102 may have a dual film consisting, for example, of an amorphous polysilicon film not containing impurities and a polysilicon film containing impurities. The conductive layer 102 may have a thickness of approximately 500 to 2000 angstroms and may be formed using, for example, a Chemical Vapor Deposition (CVD) method.

Referring to FIG. 2, a dielectric layer 106 may be formed over the semiconductor substrate, including the patterned conductive layer 102 and the tunnel oxide layer 101. The dielectric layer 106 may include a first oxide layer 103, a high dielectric layer 104, and a second oxide layer 105. The first oxide layer 103 and the high dielectric layer 104 may be sequentially formed over the semiconductor substrate, including the patterned conductive layer 102 and tunnel oxide layer 101.

The first oxide layer 103 may be formed using, for example, a High Temperature Oxide (HTO) method. The first oxide layer 103 may have a thickness of approximately 10 to 50 angstroms.

The high dielectric layer 104 may be formed using, for example, a nano-mixed method. In the nano-mixed method, the size of a crystal, which is formed using an Atomic Layer Deposition (ALD) deposition method with good step coverage, is preferably a nano scale unit. The high dielectric layer 104 may be formed by mixing Al₂O₃, with HfO₂, ZrO₂, La₂O₃, Ta₂O₅, Y₂O₃, and TiO₂ with a good current characteristic. The ratio of HfO₂, ZrO₂, La₂O₃, Ta₂O₅, Y₂O₃, and TiO₂ to Al₂0₃ may be set in the range of approximately 9:1 to 2:1. The high dielectric layer 104 may also be formed, for example, by depositing an amorphous film in situ. For example, an amorphous high dielectric layer 104 may be formed by mixing and depositing in-situ Al₂O₃ with HfO₂, ZrO₂, La₂O₃, Ta₂O₅, Y₂O₃, and TiO₂.

The high dielectric layer 104 may have a thickness of approximately 30 to 500 angstroms. The high dielectric layer 104 has a better leakage current characteristic than that of a crystal line formed through high temperature annealing, and, therefore, can improve the reliability of the flash memory device.

Referring to FIG. 3, a second oxide layer 105 and a conductive layer 107 for a control gate may be formed over the semiconductor substrate, including the high dielectric layer 104 and the first oxide layer 103. The second oxide layer 105 and a conductive layer 107 for a control gate may be formed sequentially over the semiconductor substrate. The second oxide layer 105 may be formed to a thickness of approximately 10 to 50 angstroms, using, for example, a HTO method. The conductive layer 107 may be formed using, for example, a polysilicon film containing impurities. The conductive layer 107 may have a thickness of approximately 500 to 2000 angstroms, using, for example, a CVD method.

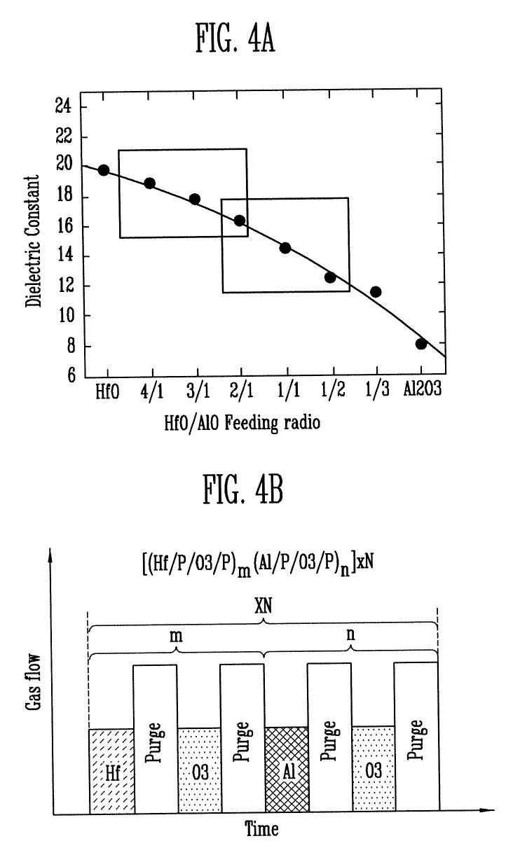

Referring to FIGS. 4A and 4B, the dielectric constant of the high dielectric layer 104 can be controlled according to the mixed ratio of a HfO gas and an AlO gas. In the high dielectric constant formation method using, for example, a nano-mixed method, Hf, O₃, Al, and O₃ gases may be sequentially implanted.

Although the foregoing description has been made with reference to the specific embodiment, it is to be understood that changes and modifications of the present invention may be made by one of ordinary skill in the art without departing from the spirit and scope of the present invention and appended claims.

What is claimed is:

1. A method of forming a dielectric layer of a flash memory device, the method comprising:
forming a tunnel oxide layer and a conductive layer for a floating gate over a semiconductor substrate;
patterning the conductive layer for the floating gate and the tunnel oxide layer;
forming a dielectric layer over the semiconductor substrate, including the patterned conductive layer for the floating gate and patterned tunnel oxide layer, wherein the dielectric layer comprises a first oxide layer, a high dielectric layer, and a second oxide layer; and
forming a conductive layer for a control gate over the semiconductor substrate, including the dielectric layer.

2. The method of claim 1, wherein the dielectric layer is formed by sequentially forming the first oxide layer, the high dielectric layer, and the second oxide layer over the semiconductor substrate, including the patterned conductive layer for the floating gate and the patterned tunnel oxide layer.

3. The method of claim 1, wherein the conductive layer for the floating gate has a dual film comprised of an amorphous polysilicon film not containing impurities and a polysilicon film containing impurities.

4. The method of claim 1, wherein the conductive layer for the floating gate has a thickness of approximately 500 to 2000 angstroms.

5. The method of claim 4, wherein the conductive layer is formed using a CVD method.

6. The method of claim 1, wherein the first oxide layer has a thickness of approximately 10 to 50 angstroms.

7. The method of claim 1, wherein the first oxide layer is formed using a HTO method.

8. The method of claim 1, wherein the high dielectric layer is formed using an ALD method.

9. The method of claim 1, wherein the high dielectric layer is formed using a nano-mixed method.

10. The method of claim 1, wherein the high dielectric layer is formed by mixing HfO₂, ZrO₂, La₂O₃, Ta₂O₅, Y₂O₃, and TiO₂ with Al₂O₃.

11. The method of claim 10, wherein the a ratio of HfO₂, ZrO₂, La₂O₃, Ta₂O₅, Y₂O₃, and TiO₂ to Al₂O₃ is in the range of approximately 9:1 to 2:1.

12. The method of claim 1, wherein the high dielectric layer has a thickness of approximately 30 to 500 angstroms.

13. The method of claim 1, wherein the high dielectric layer is formed by depositing an amorphous film in-situ.

14. The method of claim 1, wherein the second oxide layer has a thickness of approximately 10 to 50 angstroms.

15. The method of claim 14, wherein the second oxide layer is formed using a HTO method.

16. The method of claim 1, wherein the conductive layer for the control gate has a thickness of approximately 500 to 2000 angstroms.

17. The method of claim 1, wherein the conductive layer comprises a polysilicon film.

18. The method of claim 1, wherein the conductive layer is formed using a CVD method.
